(19) United States
(12) Patent Application Publication
(10) Pub. No.: US 2017/0261382 A1
(43) Pub. Date: Sep. 14, 2017

(54) SEMICONDUCTOR INTEGRATED CIRCUIT AND TEMPERATURE DETECTING DEVICE CAPABLE OF OUTPUTTING STABLE OUTPUT VOLTAGE FROM OUTPUT TERMINAL

(71) Applicant: CASIO COMPUTER CO., LTD., Tokyo (JP)

(72) Inventor: Shuhei Uchida, Tokyo (JP)

(21) Appl. No.: 15/363,751

(22) Filed: Nov. 29, 2016

(30) Foreign Application Priority Data
Mar. 10, 2016 (JP) 2016-046467

(51) Int. Cl. G01K 7/16; H01L 23/34; H01L 27/06

(52) U.S. Cl. CPC G01K 7/16; H01L 27/0629; H01L 23/34

(57) ABSTRACT

A semiconductor integrated circuit, including: a power supply input terminal to input a power supply voltage for operating the semiconductor integrated circuit; and an output terminal to output an output voltage at a same voltage level as a voltage level of the power supply voltage which is input from the power supply input terminal.

### CROSS-REFERENCE TO RELATED APPLICATION

This application is based upon and claims the benefit of priority from the prior Japanese Patent Application No. 2016-046467 filed on Mar. 10, 2016, the entire contents of which are incorporated herein by reference.

### BACKGROUND OF THE INVENTION

1. Field of the Invention

The present invention relates to a semiconductor integrated circuit and a temperature detecting device using the semiconductor integrated circuit capable of outputting a stable output voltage from an output terminal.

2. Description of Related Art

Conventionally, there has been a semiconductor integrated circuit which is referred to as a microcontroller, the semiconductor integrated circuit including a CPU (Central Processing Unit), a memory, an input/output section and various peripheral functions and controlling external equipment by performing various types of arithmetic processing by the CPU in accordance with programs stored in the memory. For example, as disclosed in Japanese Patent Application Laid Open Publication No. 2011-222844, there is widely used a general purpose input/output (GPIO) as the input/output section in the semiconductor integrated circuit, the GPIO being capable of both of input and output of signals.

FIG. 4 is a view showing an example of the configuration of a general purpose input/output.

The general purpose input/output 17 includes a P-channel MOSFET 171 (Metal-Oxide Semiconductor Field-Effect Transistor) in which a power supply voltage VDD is supplied to a source and a drain is connected to an input/output terminal T, an N channel MOSFET 172 in which a drain is connected to the drain of the P-channel MOSFET 171 and the input/output terminal T and a source is at a ground potential, and an AND circuit 173 to which a signal input from the input/output terminal T and an input enable signal IE are input. Output control signals OS1 and OS2 are respectively input to the gates of P-channel MOSFET 171 and N channel MOSFET 172.

In the general purpose input/output 17, when both of the output control signals OS1 and OS2 are at a low level (ground potential) according to a control register value for controlling the general purpose input/output 17, the P-channel MOSFET 171 is in a conduction state and the N channel MOSFET 172 is in a non-conduction state, outputting an output signal of the power supply voltage VDD from the input/output terminal T. When both of the output control signals OS1 and OS2 are at a high level (power supply voltage VDD), the P-channel MOSFET 171 is in a non-conduction state and the N channel MOSFET 172 is in a conduction state, outputting an output signal at the ground potential from the input/output terminal T. When the output control signal OS1 is at a high level and the output control signal OS2 is at a low level, both of the P-channel MOSFET 171 and the N channel MOSFET 172 are in a non-conduction state, and the input signal which was input to the input/output terminal T is latched in a latch circuit (not shown in the drawings) to be written into a register according to an input enable signal IE. In such way, signals can be input and output from a single input/output terminal T in the general purpose input/output 17. Thus, it is possible to reduce the number of terminals in the semiconductor integrated circuit and enhance the general versatility.

### SUMMARY OF THE INVENTION

An object of the present invention is to provide a semiconductor integrated circuit and a temperature detecting device which can output a more stable voltage outside.

In order to solve the above object, according to one aspect of the present invention, there is provided a semiconductor integrated circuit, including: a power supply input terminal to input a power supply voltage for operating the semiconductor integrated circuit; and an output terminal to output an output voltage at a same voltage level as a voltage level of the power supply voltage which is input from the power supply input terminal.

### BRIEF DESCRIPTION OF THE DRAWINGS

The above and other objects, advantages and features of the present invention will become more fully understood from the detailed description given hereinafter and the appended drawings which are given byway of illustration only, and thus are not intended as a definition of the limits of the present invention, and wherein:

FIG. 1 is a block diagram showing the internal configuration of a microcomputer in an embodiment according to the present invention;

FIG. 2 is a view showing the configuration of a high accuracy output section;

FIG. 3 is a schematic diagram showing the configuration of a temperature detecting device using the microcomputer; and

FIG. 4 is a view showing an example of the configuration of a general purpose input/output.

### DETAILED DESCRIPTION OF THE PREFERRED EMBODIMENT

Hereinafter, an embodiment of the present invention will be described on the basis of the drawings.

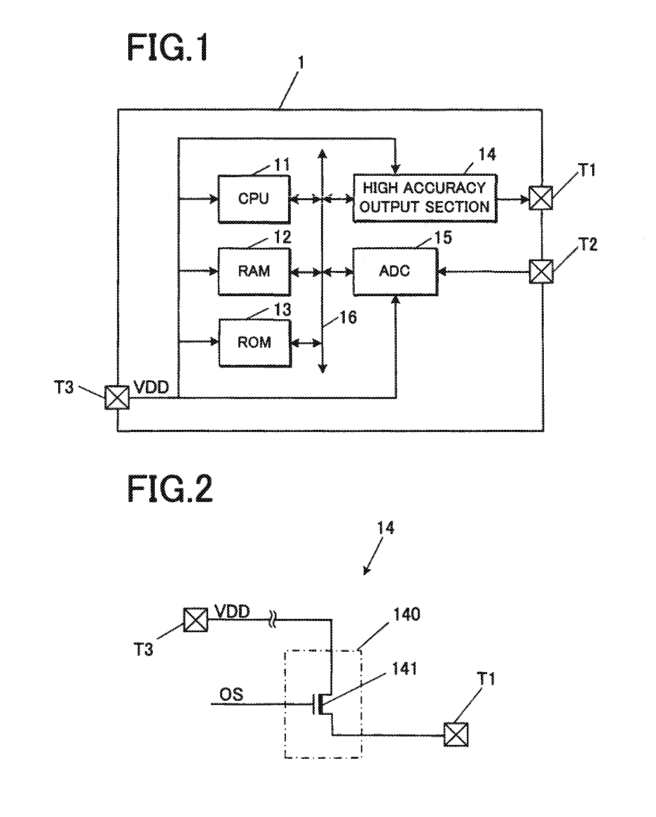

FIG. 1 is a block diagram showing the internal configuration of a microcomputer 1 (semiconductor integrated circuit) in the embodiment according to the present invention.

The microcomputer 1 includes a CPU 11, a RAM 12 (Random Access Memory), a ROM 13 (Read Only Memory), a high accuracy output section 14, an ADC 15 (analog-digital convertor), a bus 16, an output terminal T1, an input terminal T2, a power supply input terminal T3 and such like. Among them, the CPU 11, RAM 12, ROM 13, high accuracy output section 14 and ADC 15 are electrically connected to the power supply input terminal T3 and operated by the power supply voltage VDD which was input to the power supply input terminal T3. As the power supply voltage VDD, a voltage in the range of 1.5V to 5.5V can be used, for example. The microcomputer 1 can be configured as an integrated circuit formed on a single substrate.

The CPU 11 is a processor which reads out various programs and setting data stored in the ROM 13, stores them in the RAM 12 and executes the programs to perform various types of arithmetic processing.

The RAM 12 provides a working memory space to the CPU 11, and stores temporal data. The RAM 12 may include a non-volatile memory.

The ROM 13 stores various control programs executed by the CPU 11, setting data and such like. A rewritable non-volatile memory such as a flash memory may be used instead of or in addition to the ROM 13.

The high accuracy output section 14 is connected to the power supply input terminal T3 and the output terminal T1, and outputs, to the output terminal T1, an output voltage which is at a same voltage level as the power supply voltage VDD input to the power supply input terminal T3 and is stable with high accuracy.

FIG. 2 is a view showing the configuration of the high accuracy output section 14.

The high accuracy output section 14 includes a switching circuit 140 which switches between an output state of outputting an output voltage (power supply voltage VDD) from the output terminal T1 and a non-output state of not outputting the output voltage from the output terminal. The switching circuit 140 is configured by including a P-channel MOSFET 141 which has a source electrically connected to the power supply input terminal T3 and has a drain electrically connected to the output terminal T1. A power supply control signal OS is input to a gate of the P-channel MOSFET 141.

The power supply control signal OS is at a low level or at a high level (power supply voltage VDD) according to the value of a control register (not shown in the drawings) for controlling the high accuracy output section 14 which is set by the CPU 11. When the output control signal OS is at a low level and a predetermined voltage of a threshold voltage or more is applied between the source and the gate of the P-channel MOSFET 141, the P-channel MOSFET 141 is set in a conduction state, and an output voltage at a same voltage level as the power supply voltage VDD input to the source of P-channel MOSFET 141 is output from the drain of P-channel MOSFET 141 to the output terminal T1. When the output control signal OS is at a high level (power supply voltage VDD), the P-channel MOSFET 141 is set in a non-conduction state, the output terminal T1 is in a high impedance state, and the output of power supply voltage VDD from the output terminal T1 is stopped. Accordingly, the output voltage at a same voltage level as the power supply voltage VDD is output from the output terminal T1 only when the P-channel MOSFET 141 is in the conduction state.

The switching circuit 140 of the high accuracy output section 14 is configured by including only the P-channel MOSFET 141, and does not have a circuit element corresponding to the N channel MOSFET 172 which is a current leakage path in the general purpose input/output 17 in FIG. 4. Accordingly, since the switching circuit 140 of the high accuracy output section 14 does not have a current leakage path to leak the electric current flowing to the output terminal T1 in the output state, the change in the output voltage caused by leakage of the electric current is not generated in the high accuracy output section 14. As a result, in a case where the P-channel MOSFET 141 is in the conduction state, the high accuracy output section 14 outputs the output voltage at a same voltage level as the power supply voltage VDD to the output terminal T1. That is, the output voltage which is at a same voltage level as the power supply voltage VDD and is stable with high accuracy is output from the output terminal T1 of the microcomputer 1.

Here, the output voltage at a same voltage level as the power supply voltage VDD includes an output voltage having the same value as that of the power supply voltage VDD and further includes output voltages which are different from the power supply voltage VDD by the amounts of voltage decreases based on the wiring resistance of at least a part of the path leading to the output terminal T1 via the P-channel MOSFET 141 from the power supply input terminal T3.

The ADC 15 is connected to the input terminal T2, and performs digital sampling of the analog signal input from the input terminal T2 by a predetermined resolution and outputs a digital signal.

The bus 16 is a path for transmitting and receiving signals between the CPU 11, the RAM 12, the ROM 13, the high accuracy output section 14 and the ADC 15.

In addition to the above elements, the microcomputer 1 may be provided with a timer, a serial communication device such as a UART (Universal Asynchronous Receiver Transmitter), an oscillation circuit and such like as needed. In FIG. 1, input and output terminals other than the output terminal T1, the input terminal T2 and the power supply input terminal T3 are omitted. The general purpose input/output 17 shown in FIG. 4 may be used as the input and output terminals.

Next, a temperature detecting device configured by using the above-mentioned microcomputer 1 will be described.

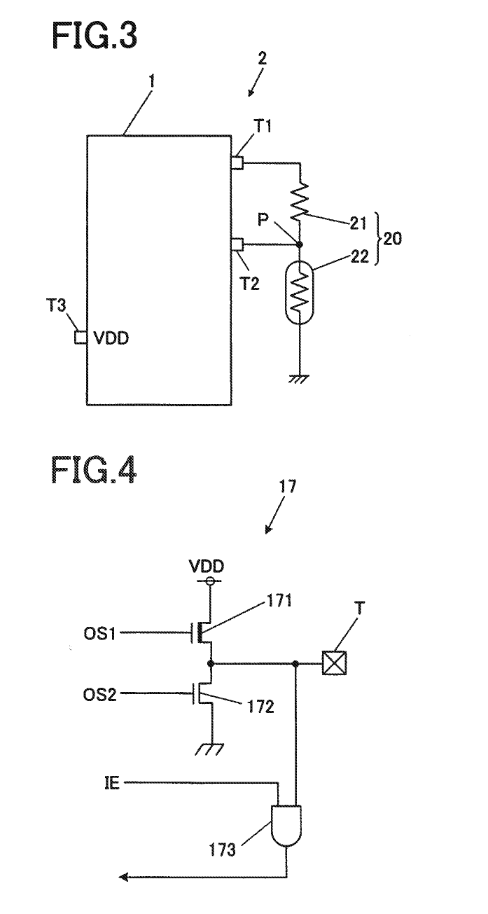

FIG. 3 is a schematic diagram showing the configuration of the temperature detecting device 2 using the microcomputer 1.

The temperature detecting device 2 includes the microcomputer 1, a fixed resistance element 21 (first resistance element) which is connected to the output terminal T1 of the microcomputer 1 and has a fixed resistance value and a variable resistance element (thermistor) 22 (second resistance element) which is connected to the fixed resistance element 21 in series and has a resistance value changing according to the temperature change. The other end of the variable resistance element 22 is at the ground potential. The connection point P between the fixed resistance element 21 and the variable resistance element 22 is connected to the input terminal T2 of the microcomputer 1. Hereinafter, the fixed resistance element 21 and the variable resistance element 22 are also collectively referred to as a temperature detecting element 20.

In the temperature detecting device 2, the voltage at the connection point P is the voltage obtained by dividing the output voltage (power supply voltage VDD) of the output terminal T1 between the fixed resistance element 21 and the variable resistance element 22. Here, the voltage at the connection point P reflects the temperature since the resistance value of the variable resistance element 22 changes according to the temperature. In the temperature detecting device 2, the temperature is detected by the microcomputer 1 on the basis of the divided voltage. That is, the voltage at the connection point P is input to the input terminal T2 of the microcomputer 1, converted into a digital signal by the ADC 15, converted into data indicating the temperature by the CPU 11, stored in the RAM 12 and output from a predetermined output terminal (not shown in the drawings) as needed.

Strictly, the resistance value of the fixed resistance element 21 slightly changes according to the temperature change. However, the above-mentioned temperature detection can be performed by the temperature detecting device 2 by using a variable resistance element 22 which has a resistance value changing according to the temperature change more greatly than the change of resistance value of the fixed resistance element.

In the temperature detecting device 2 in the embodiment, it is possible to avoid current flow to the temperature detecting element 20 when the detection of temperature is not performed by setting the P-channel MOSFET 141 of the high accuracy output section 14 connected to the output terminal T1 to the conduction state only when the detection of temperature is performed. Thus, the power consumption in the temperature detecting device 2 can be greatly reduced compared to the conventional manner of applying electric current by constantly applying the voltage to the temperature detecting element 20 from a power supply line of a circuit board on which the temperature detecting device 2 is mounted. Furthermore, since the switching element for switching the application of electric current to the temperature detecting element 20 is incorporated in the microcomputer 1, the size of circuit board to mount the temperature detecting device 2 can be greatly reduced compared to the conventional configuration of providing the switching element outside the microcomputer 1 for reducing the power consumption.

In the temperature detecting device 2 in the embodiment, when the P-channel MOSFET 141 is set in the conduction state for detecting a temperature, the leakage current is not generated in the switching circuit 140 as described above. Thus, the voltage change caused by the leakage current is not generated and the output voltage is output at a same voltage level as the power supply voltage VDD from the output terminal T1. Thus, it is possible to suppress the defect of measurement error in the detected temperature caused by the change in the output voltage from the output terminal T1.

As described above, the temperature detecting device 2 in the embodiment has features of compact size, low power consumption and high measurement accuracy, and thus, is preferable to be mounted on electronic devices such as a wristwatch (electronic timepiece) and a mobile information terminal which have large restrictions on mounting space and power consumption.

As described above, the microcomputer 1 (semiconductor integrated circuit) according to the embodiment includes a power supply input terminal T3 to input the power supply voltage VDD for operating the microcomputer 1 and an output terminal T1 to output an output voltage at a same voltage level as the power supply voltage VDD input from the power supply input terminal T3. By such configuration, a stable output voltage can be output from the output terminal T1 of the microcomputer 1.

The microcomputer 1 further includes a switching circuit 140 which switches between an output state of outputting the output voltage from the output terminal T1 and a non-output state of not outputting the output voltage from the output terminal T1. The switching circuit 140 does not have a current leakage path to leak the electric current flowing to the output terminal T1 in the output state. By such configuration, it is possible to suppress the generation of defect of change in output voltage caused by the leakage of electric current. As a result, highly accurate and stable output voltage can be output from the output terminal T1.

The switching circuit 140 is configured by including a P-channel MOSFET 141 having a drain electrically connected to the output terminal T1. By such configuration, the current leakage path is not formed between the P-channel MOSFET 141 and the output terminal T1. Thus, it is possible to surely suppress the generation of defect of change in output voltage caused by the leakage of electric current.

The power supply voltage VDD is supplied to the source of the P-channel MOSFET 141, and the P-channel MOSFET 141 outputs the output voltage at a same voltage level as the power supply voltage VDD from the drain when a predetermined voltage is applied between the gate and the source to set the P-channel MOSFET 141 in the conduction state. By such configuration, it is possible to output the output voltage which is at a same voltage level as the power supply voltage VDD and is stable with high accuracy from the output terminal T1 connected to the drain of P-channel MOSFET 141.

The temperature detecting device 2 according to the embodiment includes: a microcomputer 1 including a power supply input terminal T3 to input the power supply voltage VDD for operating the microcomputer 1 and an output terminal T1 to output an output voltage at a same voltage level as that of the power supply voltage VDD input from the power supply input terminal T3; and a temperature detecting element 20 having a fixed resistance element 21 and a variable resistance element 22 which is connected to the fixed resistance element 21 in series and has a resistance value changing according to the temperature change more greatly than that of the fixed resistance element 21. The output voltage output from the output terminal T1 of the microcomputer 1 is applied to the temperature detecting element 20. The microcomputer 1 has the input terminal T2 to input the voltage obtained by dividing the output voltage between the fixed resistance element 21 and the variable resistance element 22, and detects the temperature on the basis of the voltage which was input to the input terminal T2. By such configuration, the output voltage which is stable with high accuracy is applied to the temperature detecting element 20. Thus, it is possible to suppress the generation of defect of measurement error in the detected temperature caused by the change in voltage applied to the temperature detecting element 20. Further, since the output voltage is output from the output terminal T1 only when detecting the temperature, it is possible to avoid current flow to the temperature detecting element 20 when not performing the temperature detection. Thus, the power consumption in the temperature detecting device 2 can be reduced. Since the microcomputer 1 incorporates therein the switching circuit 140 which switches between application and non-application of the output voltage to the temperature detecting element 20, the size of circuit board to mount the temperature detecting device 2 can be reduced.

The present invention is not limited to the embodiment, and various changes can be made.

For example, the embodiment has been described by taking, as an example, the switching circuit 140 configured by including a single P-channel MOSFET 141. However, the present invention is not limited to this. The configuration of the switching circuit 140 can be appropriately changed within the range of satisfying the condition that the supply and stop of power supply voltage VDD to the output terminal 1 can be switched and the switching circuit 140 does not have a current leakage path to leak the electric current flowing to the output terminal T1 in a state in which the power supply voltage VDD is supplied.

The embodiment has been described by using an example of applying the microcomputer 1 to the temperature detecting device 2. However, the present invention is not limited to this, and the microcomputer 1 can be applied to various devices which require the supply of highly accurate stable voltage.

Though several embodiments of the present invention have been described above, the scope of the present invention is not limited to the above embodiments, and includes the scope of inventions, which is described in the scope of claims, and the scope equivalent thereof.

What is claimed is:

1. A semiconductor integrated circuit, comprising:
a power supply input terminal to input a power supply voltage for operating the semiconductor integrated circuit; and
an output terminal to output an output voltage at a same voltage level as a voltage level of the power supply voltage which is input from the power supply input terminal.

2. The semiconductor integrated circuit according to claim 1, further comprising a switching circuit which switches between an output state of outputting the output voltage from the output terminal and a non-output state of not outputting the output voltage from the output terminal, wherein
the switching circuit does not have a current leakage path to leak an electric current flowing to the output terminal in the output state.

3. The semiconductor integrated circuit according to claim 2, wherein the switching circuit includes a P-channel MOSFET which has a drain electrically connected to the output terminal.

4. The semiconductor integrated circuit according to claim 3, wherein
the power supply voltage is supplied to a source of the P-channel MOSFET, and
the P-channel MOSFET outputs an output voltage at the same voltage level as the voltage level of the power supply voltage from the drain when a predetermined voltage is applied between a gate and the source to set the P-channel MOSFET in a conduction state.

5. A temperature detecting device, comprising:
a semiconductor integrated circuit which includes:
a power supply input terminal to input a power supply voltage for operating the semiconductor integrated circuit; and
an output terminal to output an output voltage at a same voltage level as a voltage level of the power supply voltage which is input from the power supply input terminal; and
a temperature detecting element which has a first resistance element and a second resistance element that is connected to the first resistance element in series and has a resistance value changing according to a temperature change more greatly than a change of a resistance value of the first resistance element, wherein
the output voltage which is output from the output terminal of the semiconductor integrated circuit is applied to the temperature detecting element, and
the semiconductor integrated circuit has an input terminal to input a voltage obtained by dividing the output voltage between the first resistance element and the second resistance element, and the semiconductor integrated circuit detects a temperature on the basis of the voltage which is input to the input terminal.

6. The temperature detecting device according to claim 5, further comprising a switching circuit which switches between an output state of outputting the output voltage from the output terminal and a non-output state of not outputting the output voltage from the output terminal, wherein
the switching circuit does not have a current leakage path to leak an electric current flowing to the output terminal in the output state.

7. The temperature detecting device according to claim 6, wherein the switching circuit includes a P-channel MOSFET which has a drain electrically connected to the output terminal.

8. The temperature detecting device according to claim 7, wherein
the power supply voltage is supplied to a source of the P-channel MOSFET, and
the P-channel MOSFET outputs an output voltage at the same voltage level as the voltage level of the power supply voltage from the drain when a predetermined voltage is applied between a gate and the source to set the P-channel MOSFET in a conduction state.
